(19) United States
(12) Patent Application Publication
(10) Pub. No.: US 2003/0062150 A1
(43) Pub. Date: Apr. 3, 2003

(54) Temperature/strain control of fatigue vulnerable devices used in electronic circuits

(76) Inventors: Melissa Sweitzer, Honeye Falls, NY (US); Michael Wolfinger, New London, NH (US)

Correspondence Address: HARNESS, DICKEY & PIERCE, P.L.C., P.O. BOX 828, BLOOMFIELD HILLS, MI, 48303, US

(21) Appl. No.: 09/962,951

(22) Filed: Sep. 25, 2001

(51) Int. Cl. H05K 7/20

(52) U.S. Cl. 165/104.33; 361/700; 62/3.3

(57) ABSTRACT

A temperature control system and method reduces thermal/strain fatigue failures in connections between first and second circuit elements of an electronic circuit. A temperature control device is in a heat exchange relationship with at least one of the first and second circuit elements. The temperature control device maintains a temperature of the first and second circuit elements below a predetermined high temperature and above a predetermined low temperature when the electronic circuit is operating and when the electronic circuit is not operating to reduce thermally-induced fatigue of the connection. The coefficients of thermal expansion (CTE) of the first and second circuit elements are also matched. The temperature control device includes a thermoelectric heat pump, a heat pipe, a finned heat exchanger, a phase change heat transfer device, a heat sink and/or any other suitable temperature control device.

### FIELD OF THE INVENTION

The present invention relates to methods and apparatus for reducing temperature and strain fatigue, and more particularly to methods and apparatus for reducing temperature and strain fatigue of circuit elements that are connected together in an electronic circuit.

### BACKGROUND OF THE INVENTION

Electronic circuits often include circuit elements that are connected together using solder, a metallic-filled epoxy such as silver-filled epoxy, explosive bonding, or electrical leads that project from a circuit package. During operation, the electronic circuit typically experiences significantly higher operating temperatures due to current flow and higher environmental temperature due to other hot devices in the same vicinity. The heating and cooling of the electronic circuit strains the connection between the circuit elements, particularly when the circuit elements are fabricated using materials with different coefficients of thermal expansion (CTE).

Typical operating temperatures for electronic circuits generally range between 70° C. and 150° C. These electronic circuits sometimes include a fan or other mechanism for cooling the electronic circuit during operation. Oftentimes, the fan cools the electronic circuit for a brief period after the electronic circuit is turned off. Some time after being turned off, the electronic circuit cools down to ambient temperature, which is typically between 20-25° C.

Conventional methods for decreasing thermal fatigue failure of electronic circuits typically involve matching the CTEs of the materials that are used to fabricate the circuit elements. By matching the CTEs, the induced strain is minimized for a given temperature change. However, there is a practical limitation on how well the CTEs can be matched due to other constraints that must be accommodated in the design of the electronic circuit. These other constraints include the cost of the materials, the thermal conductivity of the materials, and the ease of manufacture. Once the materials are selected, the statistical failure rate of the electronic circuit as a function of the number of thermal cycles can be predicted with a relatively high statistical probability.

### SUMMARY OF THE INVENTION

A system and method according to the present invention reduces thermally-induced fatigue failures in electronic circuits. The electronic circuit includes first and second circuit elements that are connected together. A temperature control device is in a heat exchange relationship with at least one of the first and second circuit elements. The temperature control device maintains a temperature of the first and second circuit elements below a predetermined high temperature and above a predetermined low temperature when the electronic circuit is operating and when the electronic circuit is not operating to reduce temperature/strain fatigue.

In other features of the invention, the first circuit element is fabricated from a first material having a first coefficient of thermal expansion (CTE). The second circuit element is fabricated from a second material having a second CTE that approximately matches the first CTE. The temperature control device is connected to both the first and the second circuit elements. The first and second circuit elements are connected together using solder, a metallic-filled epoxy, explosive bonding, or other practical methods.

In yet other features, the temperature control device includes a thermoelectric heat pump, a heat pipe, a finned heat exchanger, a phase change heat transfer device, a heat sink and/or any other suitable temperature control device. The temperature control device preferably operates in a closed-loop manner to control the temperature of the first and second circuit elements.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

The present invention will become more fully understood from the detailed description and the accompanying drawings, wherein:

FIG. 1 is a plot of strain amplitude vs. reversals to failure on a log-log scale;

FIG. 2A illustrates a temperature control device that is in a heat exchange relationship with first and second circuit elements of an electronic circuit;

FIG. 2B illustrates a temperature control device that is in a heat exchange relationship with a second circuit element of an electronic circuit;

FIG. 2C illustrates a temperature control device that is in a heat exchange relationship with a first circuit element of the electronic circuit;

FIG. 3 illustrates a first embodiment of the temperature control device that includes a thermoelectric heat pump;

FIG. 4 illustrates a second embodiment of the temperature control device that includes a heat pipe;

FIG. 5 illustrates a third embodiment of the temperature control device that includes a finned heat exchanger through which coolant flows;

FIG. 6 illustrates a fourth embodiment of the temperature control device that includes a finned heat exchanger through which air flows;

FIG. 7 illustrates a fifth embodiment of the temperature control device that includes a phase change heat transfer device;

FIG. 8 illustrates a sixth embodiment of the temperature control device that includes a cold plate having a circuit element connected to a fluid inlet thereof; and

FIG. 9 illustrates a seventh embodiment of the temperature control device that includes an exemplary closed-loop temperature controller.

### DETAILED DESCRIPTION OF THE PREFERRED EMBODIMENTS

The following description of the preferred embodiment(s) is merely exemplary in nature and is in no way intended to limit the invention, its application, or uses.

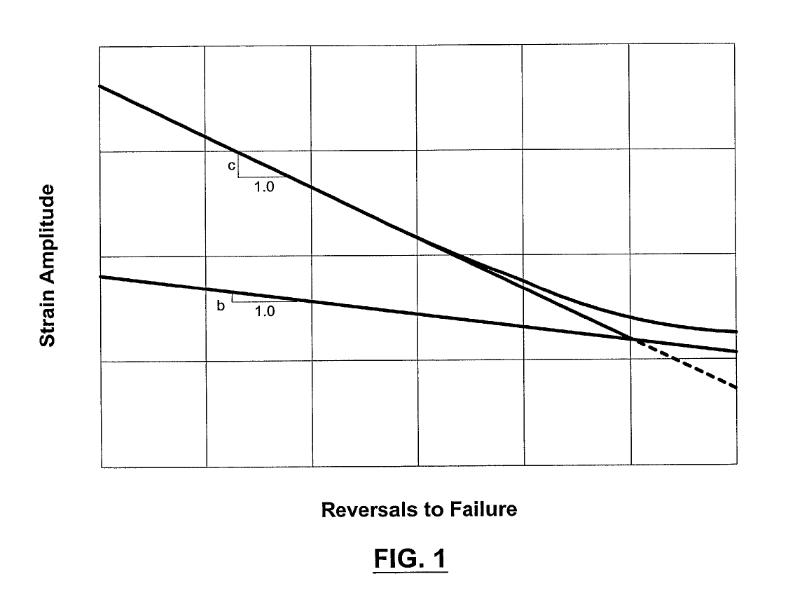

When an electronic circuit is subjected to thermally varying conditions, the electronic circuit fails in a predictable manner. FIG. 1 illustrates the number of cycles or reversals to failure as a function of strain amplitude. The relationship between the number of reversals and strain is defined by the following functions:

$$\frac{Δ {ϵ}_{p}}{2} = {{ϵ}_{f} ( 2 {N}_{f} )}^{c} \qquad [ 1 ]$$

σₐ=σ_{f}(2N_{f})^{b} [2]

Where a fatigue ductility coefficient (ε′_{f}) is the true strain corresponding to fracture inone reversal; fatigue strength coefficient (σ′_{f}) is the true stress corresponding to fracture in one reversal; fatigue ductility exponent (c) is the slope of the plastic strain line; fatigue strength exponent (b) is the slope of the elastic strain line; εₚ is the plastic strain amplitude; σₐ is the elastic stress amplitude; and N_{f} is the number of cycles to failure.

Since the total strain is composed of the two components of plastic and elastic strain:

ε_{Total}=εₚ+εₑ [3]

In terms of strain amplitudes:

Δε_{Total}=Δεₚ+Δεₑ [4]

Or:

$$\frac{Δ {ϵ}_{Total}}{2} = \frac{Δ {ϵ}_{p}}{2} + \frac{Δ {ϵ}_{e}}{2} \qquad [ 5 ]$$

Also, from Hooke's Law:

$$\frac{Δ {ϵ}_{e}}{2} = \frac{{σ}_{a}}{E} \qquad [ 6 ]$$

Then, dividing equation 2 by the Elastic Modulus, E:

$$\frac{{σ}_{a}}{E} = \frac{{σ}_{f}}{E} {( 2 {N}_{f} )}^{b} = \frac{Δ {ϵ}_{e}}{E} \qquad [ 7 ]$$

An equation for the cyclical strain-based approach to fatigue life which is often called the strain-life relation is produced by combining [7], [5], and [1]:

$$\frac{Δ {ϵ}_{total}}{2} = \frac{{σ}_{f}}{E} {( 2 {N}_{f} )}^{b} + {{ϵ}_{f} ( 2 {N}_{f} )}^{c} \qquad [ 8 ]$$

The graph of the total strain that is induced has both a plastic element and an elastic element. In low-cycle fatigue, 2N_{f}<2Nₜ, the plastic strain dictates the life of the part. In high-cycle fatigue, 2N_{f}>2Nₜ, the elastic strain plays the dominant role. In either of these situations, the number of cycles to failure is an exponential function of the strain amplitude. For thermally induced strain, the magnitude of the amplitude is the maximum strain minus the minimum strain. As these values occur at the maximum and minimum values of temperature, it becomes apparent that by limiting temperature excursion, the life of the part will increase significantly. The following example illustrates the concepts discussed above:

A transistor is soldered to a copper spreader plate. A part is heat sunk to a copper cold plate with 25° C. water flowing at 2 gpm. The transistor dissipation is 125 watts maximum, 0 watts minimum. An ANSYS FEA program was used to calculate the temperature and strain distributions. The solder composition used has the following fatigue properties:

ε′_{f}=0.325,c=−0.4σ′_{f}=24977,b=−0.4 [9]

The strain can be read from the FEA output:

ε_{MAX}=0.010016 [10]

The minimum dissipation condition is zero, so the strain amplitude is equal to the strain value at the minimum dissipation condition. Applying equation [9]:

$$\frac{.010016}{2} = \frac{24977}{1700000} {( 2 {N}_{f} )}^{- .4} + .325 {( 2 {N}_{f} )}^{- .4} ⇒ {N}_{f} = 19000 \qquad [ 11 ]$$

In order to increase the estimated life of the part, the baseplate was changed to a copper-molybdenum clad material. The thermal conductivity of the clad material is is lower but the CTE is a much better match to the silicon. Classically, matching CTEs has been the only approach that is used to minimize the thermally induced strain of the part. The following illustrations were taken from the finite element analysis of this structure: the strain from the FEA output:

ε_{MAX}=0.0062 [12]

Since the minimum dissipation condition is zero, the strain amplitude is equal to the maximum value. Applying equation [9]:

$$\frac{.0062}{2} = \frac{24977}{1700000} {( 2 {N}_{f} )}^{- .4} + .325 {( 2 {N}_{f} )}^{- 4} ⇒ {N}_{f} = 63000 \qquad [ 13 ]$$

In order to get more life out of the part, the present invention employs a temperature control device to actively heat and cool the device during operation and when shut off to limit temperature excursion.

Reading the strain from the FEA output:

ε_{MIN}=0.003975 [14]

Calculating the strain amplitude:

Δε_{TOTAL}=ε_{MAX}−ε_{MIN}=0.0062−0.003975=0.002225 [15]

Applying Equation [9]:

$$\frac{.002225}{2} = \frac{24977}{1700000} {( 2 {N}_{f} )}^{- 4} + .325 {( 2 {N}_{f} )}^{- .4} ⇒ {N}_{f} = 815000 \qquad [ 16 ]$$

By managing both the CTE and the temperature excursion, it is possible to significantly increase the expected life of the device by almost two orders of magnitude:

### Summary of Results for Example

| Description | Strain Amplitude | Cycles to Failure |
|---|---|---|
| Original Part | .010016 | 19000 |
| CTE Matched Part | .0062 | 63000 |
| CTE + Thermal Control | .002225 | 815000 |

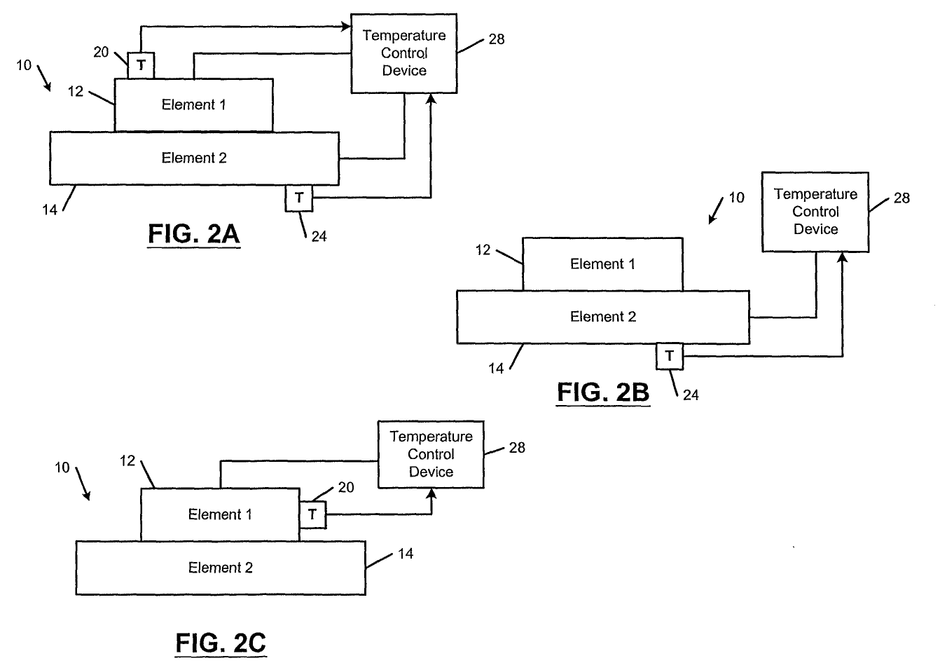

Referring now to FIG. 2A, an electronic circuit 10 includes a first circuit element 12 that is connected to a second circuit element 14. The first circuit element 12 and the second circuit element 14 are connected using solder, metallic-filled epoxy (such as silver-filled epoxy), explosive bonding, electrical leads, or any other suitable connection that is subjected to thermally induced strain fatigue. The connection is subjected to temperature induced strain fatigue due to the difference in connection temperature that occurs when the circuit is operating and when the circuit is shut off.

A first temperature sensor 20 is optionally connected to the first circuit element 12 and provides a first temperature signal that is proportional to the temperature of the first circuit element 12. A second temperature sensor 24 is optionally connected to the second circuit element 14 and provides a second temperature signal that is proportional to the temperature of the second circuit element 14. The first and second temperature sensors 20 and 24 are preferably employed with a closed-loop temperature control devices 28 as will be described further below. As can be appreciated by skilled artisans, the first and second temperature sensors 20 and 24 are not required for open-loop temperature control devices 28. If the temperature sensors 20 and 24 are used, the temperature control device 28 receives the first and second temperature signals from the first and second temperature sensors 20 and 24. The temperature control device 28 varies the temperature of the first and second circuit elements 12 and 14 to maintain the temperature of the first and second circuit elements 12 and 14 between upper and lower predetermined temperature values that define a temperature window. The temperature window is defined to limit temperature excursion of the electronic circuit 10.

For example, electronic circuits 10 are often operated during first and second work shifts and turned off during a third work shift. The electronic circuit 10 typically has an operating temperature that is approximately between 70° C. and 150° C. Therefore, during the first and second shifts the electronic circuit 10 operates at a relatively high temperature that is approximately between 70° C. and 150° C. When the electronic circuit 10 is turned off during the third shift, the temperature of the electronic circuit 10 falls to the ambient temperature that is approximately 20-25° C. In other words, the width of the temperature window is approximately between 50-125° C. The temperature window according to the invention is controlled or managed to less than 30° C. More particularly, the temperature window is preferably less than 20° C. In a more preferred embodiment, the temperature window is less than 15° C. As the temperature window is decrease, the life of the part increases.

For purposes of clarity reference numbers from FIG. 2A have been used in FIGS. 2B and 2C where appropriate to identify the same elements. The embodiments shown in FIGS. 2B and 2C rely on heat diffusion from the second circuit element 14 to the first circuit element 12 (FIG. 2B) or from the first circuit element 12 to the second circuit element 14 (FIG. 2C). In the embodiments shown in FIGS. 2A, 2B, and 2C, the temperature control device 28 controls the temperature of the first and second circuit elements 12 and 14 when the electronic circuit 10 is operating and when the electronic circuit 10 is shut off. In other words, the temperature control device 28 supplies heat to the first and second circuit elements 12 and 14 to maintain the lower predetermined temperature and cools the first and second circuit elements 12 and 14 to maintain the upper predetermined temperature on an as-needed basis.

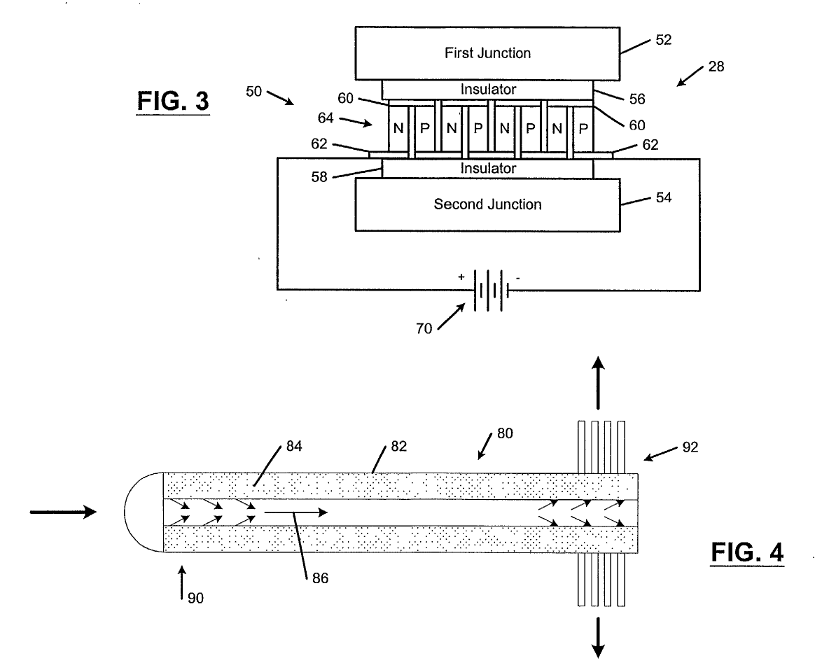

Referring now to FIG. 3, a first embodiment of the temperature control device 28 is illustrated and includes one or more thermoelectric heat pumps 50. The thermoelectric heat pump 50 includes a first junction 52, a second junction 54, electrical insulators 56 and 58, and electrical conductors 60 and 62. A plurality of semiconductor portions 64 are located between the conductors 60 and 62 and are heavily doped to create either an excess of electrons (N-type) or a deficiency of electrons (P-type). In one mode, heat that is absorbed at the first junction 52 is pumped to the second junction 54 at a rate that is proportional to current passing through a bias circuit 70. Switching the polarity of the bias circuit 70 reverses the flow of heat between the first and second junctions 52 and 54. As can be appreciated, one or more thermoelectric heat pumps 50 can be used to control the heating and cooling of the first and second circuit elements 12 and 14. The thermoelectric heat pump 50 can also be combined with one or more other heating and/or cooling devices. Suitable thermoelectric heat pumps are available from sources such as Melcor, Inc.

Referring now to FIG. 4, a second embodiment of the temperature control device 28 includes one or more heat pipes 80. The heat pipe 80 includes a vacuum envelope 82, a wick structure 84, and a working fluid 86 such as water. The heat pipe 80 is evacuated and then back-filled with a small amount of the working fluid 86. The amount of working fluid 86 is preferably enough to saturate the wick structure 84. The atmosphere inside of the heat pipe 80 is set by an equilibrium of liquid and vapor. As heat enters an evaporator end 90, the equilibrium is upset and vapor is generated at a slightly higher pressure. The higher pressure vapor travels to a condenser end 92 where the slightly lower temperature causes the vapor to condense and give up its latent heat of vaporization. The condensed fluid is pumped back to the evaporator end 90 by the capillary force developed in the wick structure 84. This continuous cycle transfers a large quantity of heat with very low thermal gradients. The passive operation of the heat pipe 80 produces a relatively long life. Multiple heat pipes 80 can be packaged in a carrier. The equilibrium point and orientation of the heat pipes 80 can be adjusted to provide both heating and cooling. The heat pipe 80 can be combined with one or more other heating and cooling devices. The heat pipe 80 can be a heat pipe or a heat sink that is available from sources such as Thermacore, Inc.

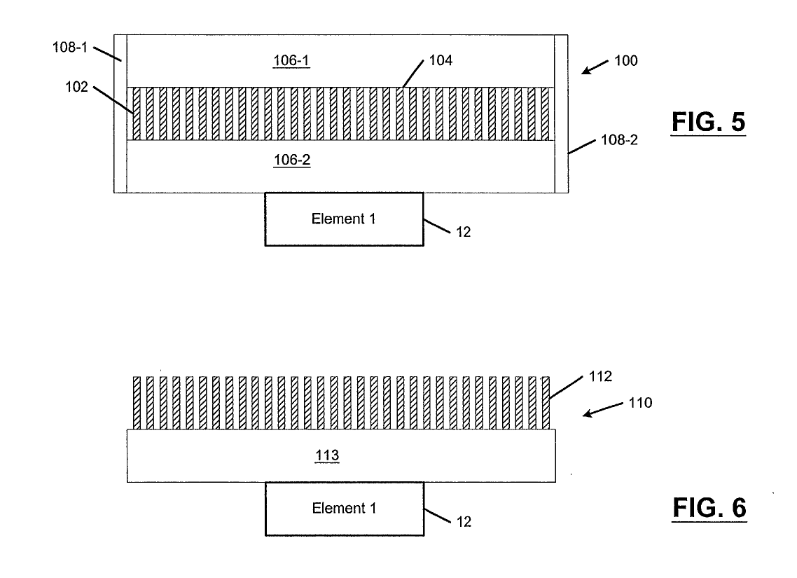

Referring now to FIG. 5, a third embodiment of the temperature control device 28 is illustrated and includes a fluid-based finned heat exchanger 100. The finned heat exchanger 100 includes a plurality of fins 102 that are located in a cavity 104 defined by top plates 106-1 and 106-2 and side plates 108-1 and 108-2. A fluid such as water, coolant or another fluid flows through the cavity 104 and establishes a heat exchange relationship with the fins 102. As can be appreciated, the temperature of the fluid flowing through the cavity 104 can be controlled to vary the temperature of the finned heat exchanger 100, which in turn varies the temperature of the first circuit element 12 (and/or the second circuit element 14) that is connected thereto. As can be appreciated, surfaces of the first circuit element 12 can be used as a substitute for one or more of the plates 106 and 108. A temperature conditioning device (not shown) such as a heater/chiller can be used to vary the temperature of the fluid. The heat exchanger can be combined with one or more other heating and cooling devices.

Referring now to FIG. 6, a fourth embodiment of the temperature control device 28 is illustrated and includes a gas-based finned heat exchanger 110. The finned heat exchanger 110 includes a plurality of fins 112 that extend from a plate 113. A gas such as air establishes a heat exchange relationship with the fins 102. As can be appreciated, the temperature of the gas flowing across the fins 102 varies the temperature of the finned heat exchanger 100, which in turn varies the temperature of the first circuit element 12 (and/or the second circuit element 14) that is connected thereto. As can be appreciated, surfaces of the first circuit element 12 can be used as a substitute for the plate 113. A temperature conditioning device (not shown) such as a gas heater/chiller can be used to vary the temperature of the gas. The heat exchanger 110 can be combined with one or more other heating and cooling devices.

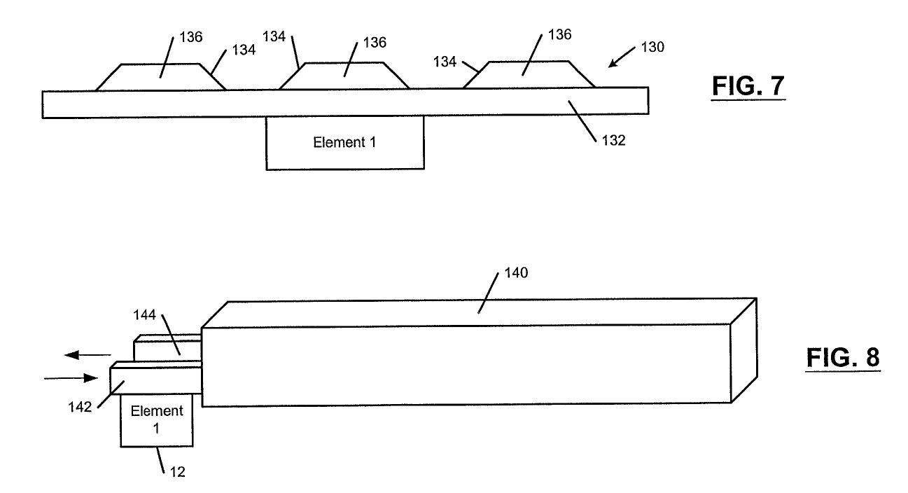

Referring now to FIG. 7, a fifth embodiment of the temperature control device 28 is illustrated and includes a phase change heat transfer device 130. The phase change heat transfer device 130 includes a base 132 that conducts heat and a plurality of phase change capsules 134 that contain a phase change material 136. The phase change material 136 has a large quantity of energy in the form of latent heat that needs to be absorbed or released when the material changes from a solid to a liquid state (melting) or from the liquid to the solid state (freezing). The phase changes typically take place at constant temperature and the phase change process can be repeated over an unlimited number of cycles with no change in the physical or chemical properties of the material. One suitable phase change material 136 is an inorganic hydrated salt. The salt melts at a constant temperature while the electronic circuit 10 is on and heat is absorbed. When the electronic circuit 10 is turned off, the salt solidifies and generates heat. The phase change heat transfer device 130 can be combined with one or more other heating and cooling devices. One suitable phase change heat transfer device 130 is available from sources such as PCM Thermal Solutions.

Referring now to FIG. 8, a sixth embodiment of the temperature control device 28 is illustrated and includes a cold plate 140 (or a heat sink). The first circuit element 12 (and/or the second circuit element 14) is connected to a fluid inlet 142 or a fluid outlet 144 of the cold plate 140. Preferably, the fluid inlet 142 and the fluid outlet 144 are made of a temperature conductive material such as copper. The temperature of the first circuit element 12 is maintained at the temperature of the fluid that flows through the fluid inlet 142 (and/or the fluid outlet 144). The fluid can be water, coolant or any other suitable fluid. The cold plate can be combined with one or more other heating and cooling devices.

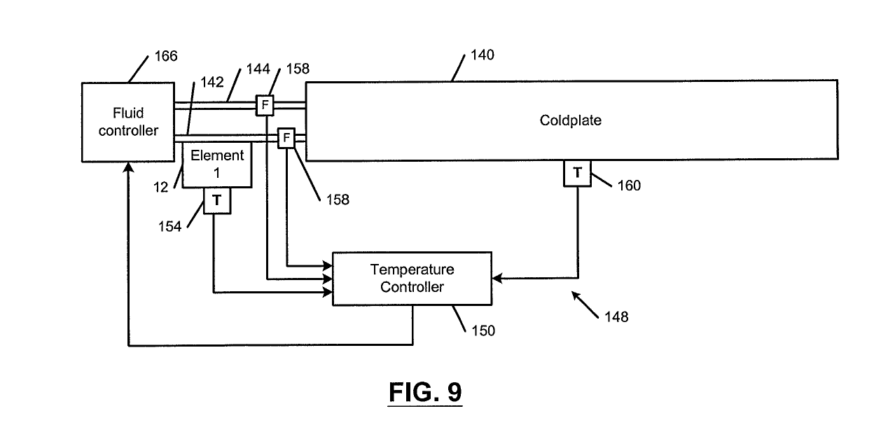

For purposes of clarity, reference numbers from FIG. 8 are used in FIG. 9 where appropriate to identify the same elements. FIG. 9 shows a seventh embodiment of the temperature control device 28 that includes a temperature control system 148 with a temperature controller 150. While the temperature controller 150 is shown in conjunction with the embodiment of FIG. 9, skilled artisans can appreciate that the temperature controller 150 can be readily adapted to the other embodiments of FIGS. 2-8. A third temperature sensor 154 is connected to the first circuit element 12. One or more mass flow sensors 158 provide a mass flow signal that is based on the amount of fluid flowing through the fluid inlet 142 and/or the fluid outlet 144. The mass flow sensor 158 provides an indication relating to heating/cooling capacity of the temperature control device 28. In other systems, pressure, voltage, current, etc. may be used as feedback. An optional fourth temperature sensor 160 generates a temperature signal that is proportional to the temperature of the cold plate 140, the fluid flowing at the fluid inlet 142, the fluid flowing at the fluid outlet 144, or any other temperature feedback. A fluid controller 166 receives control signals from the temperature controller 150 and is connected to the fluid inlet 142 and/or the fluid outlet 144. The fluid controller 166 receives one or more control signals from the temperature controller 150. The fluid controller 166 adjusts the fluid flow into the cold plate 140 and/or adjusts the temperature of the fluid to vary the temperature of the first and/or second circuit elements.

As can be appreciated by skilled artisans, all of the temperature control devices 28 can employ closed loop control methods for controlling the temperature of the first circuit element 12 and/or the second circuit element 14. In addition, the temperature control device 28 can also employ software that is executed by a processor and memory to provide the appropriate temperature control. In addition, the CTEs of materials that are used to fabricate the first circuit element 12 are matched with the CTEs of materials that are used to fabricate the second circuit element 14. By using both temperature control and matching the CTEs, the life of the electronic circuit 10 can be dramatically improved. The present invention also contemplates combining one or more of the embodiments to control the temperature of the first and second circuit elements 12 and 14. The present invention is particularly applicable to industrial processing systems such as those used for manufacturing silicon wafers for chip production, compact disks, digital video disks, computer hard drives, and any other electronic device.

Those skilled in the art can now appreciate from the foregoing description that the broad teachings of the present invention can be implemented in a variety of forms. Therefore, while this invention has been described in connection with particular examples thereof, the true scope of the invention should not be so limited since other modifications will become apparent to the skilled practitioner upon a study of the drawings, the specification and the following claims.

What is claimed is:

1. A system for reducing thermally-induced fatigue failures in electronic circuits, comprising:
a first circuit element;
a second circuit element;
a connection between said first and second circuit elements; and
a temperature control device that is in a heat exchange relationship with at least one of said first and second circuit elements, that maintains a temperature of said at least one of first and second circuit elements below a predetermined high temperature and above a predetermined low temperature when said electronic circuit is operating and when said electronic circuit is not operating to reduce thermally/strain fatigue of said connection.

2. The system of claim 1 wherein said first circuit element is fabricated from a first material having a first coefficient of thermal expansion (CTE) and said second circuit element is fabricated from a second material having a second CTE that approximately matches said first CTE.

3. The system of claim 1 wherein said temperature control device is connected to both said first and said second circuit elements.

4. The system of claim 1 wherein said connection is at least one of solder, metallic-filled epoxy, and explosive bonding.

5. The system of claim 1 wherein said temperature control device includes a thermoelectric heat pump.

6. The system of claim 1 wherein said temperature control device includes a heat pipe.

7. The system of claim 6 wherein said heat pipe includes:
a warm end;
a cool end;
a vacuum-tight envelope;
a wick structure; and
a working fluid, wherein said working fluid is wicked by said wick structure, evaporated at said warm end and condensed at said cool end to transfer heat.

8. The system of claim 1 wherein said temperature control device includes a finned heat exchanger.

9. The system of claim 8 wherein said finned heat exchanger exchanges heat with a fluid.

10. The system of claim 8 wherein said finned heat exchanger exchanges heat with gas.

11. The system of claim 1 wherein said temperature control device includes a phase change heat transfer device that employs one of a latent heat of vaporization to increase said temperature of said one of said first and second circuit elements and a latent heat of fusion to decrease said temperature of said one of said first and second circuit elements.

12. The system of claim 1 wherein said temperature control device includes a cold plate having a fluid inlet and a fluid outlet.

13. The system of claim 12 wherein said one of said first and second circuit elements is connected to one of said fluid inlet and said fluid outlet.

14. The system of claim 13 further comprising:
a controller;
a temperature sensor connected to said one of said first and second circuit elements;
a flow sensor connected to one of said fluid inlet and said fluid outlet; and
a flow control device,
wherein said controller adjusts said flow control device based on an output of said temperature sensor and said flow sensor.

15. A method for reducing thermally-induced fatigue failures in electronic circuits, comprising the steps of:
providing first and second circuit elements;
connecting said second circuit element to said first circuit element;
coupling a temperature control device to at least one of said first and second circuit elements; and
controlling a temperature of said at least one of said first and second circuit elements within a temperature window using said temperature control device when said electronic circuit is operating and when said electronic circuit is not operating to reduce temperature/strain fatigue.

16. The method of claim 15 further comprising the step of selecting a first coefficient of thermal expansion (CTE) for said first circuit element that approximately matches a second CTE of said second circuit element.

17. The method of claim 15 wherein said temperature control device includes a thermoelectric heat pump.

18. The method of claim 15 wherein said temperature control device includes a heat pipe.

19. The method of claim 18 wherein said heat pipe includes:
a warm end;
a cool end;
a vacuum-tight envelope;
a wick structure; and
a working fluid, and further comprising the steps of:
wicking said working fluid from said cool end to said warm end;
evaporating said working fluid as said warm end; and
condensing said working fluid at said cool end.

20. The method of claim 15 wherein said temperature control device includes a finned heat exchanger.

21. The method of claim 20 wherein said finned heat exchanger exchanges heat with a fluid.

22. The method of claim 20 wherein said finned heat exchanger exchanges heat with gas.

23. The method of claim 15 wherein said temperature control device includes a phase change heat transfer device.

24. The method of claim 23 further comprising the step of employing a latent heat of vaporization to increase said temperature of said one of said first and second circuits elements.

25. The method of claim 23 further comprising the step of employing a latent heat of fusion to decrease a temperature of said one of said first and second circuit elements.

26. The method of claim 15 wherein said temperature control device includes a cold plate having a fluid inlet and a fluid outlet.

27. The method of claim 26 wherein said one of said first and second circuit elements is connected to one of said fluid inlet and said fluid outlet.

28. The method of claim 27 further comprising:
a controller;
a temperature sensor connected to said one of said first and second circuit elements;
a flow sensor connected to said inlet; and
a flow control device,
wherein said controller adjusts said flow control device based on an output of said temperature sensor and said flow sensor.

29. The method of claim 28 further comprising the step of adjusting said flow control device based on an output of said temperature sensor and said flow sensor.
